(19) United States
(12) Patent Application Publication
(10) Pub. No.: US 2021/0208201 A1
(43) Pub. Date: Jul. 8, 2021

(54) BATTERY MONITORING DEVICE

(71) Applicant: DENSO CORPORATION, Kariya-city (JP)

(72) Inventors: Isao ISHIBE, Kariya-city (JP); Syunya YAMAMOTO, Kariya-city (JP)

(21) Appl. No.: 17/207,249

(22) Filed: Mar. 19, 2021

Related U.S. Application Data
(63) Continuation of application No. PCT/JP2019/036348, filed on Sep. 17, 2019.

(30) Foreign Application Priority Data
Sep. 21, 2018 (JP) 2018-177404

(51) Int. Cl. G01R 31/3835; H02J 7/00; G01R 31/396; H01M 10/48

(52) U.S. Cl. CPC G01R 31/3835; H01M 10/482; G01R 31/396; H02J 7/0047

(57) ABSTRACT

In a battery monitoring device, a plurality of short-circuit switches are correspondingly provided for a plurality of battery cells of an assembled battery through detection lines. The battery cells includes a first battery cell and a second battery cell adjacent to each other. The short-circuit switches includes a first switch and a second switch, respectively, corresponding to the first battery cell and the second battery cell. An abnormality determination circuit executes an on and off control to turn the second switch from an off state to an on state, and then to the off state again while keeping the first switch in an off state. The abnormality determination circuit determines an abnormality of a detection line based on detection voltages of the first battery cell and detection voltages of the second battery cell before and after execution of the on and off control.

### CROSS REFERENCE TO RELATED APPLICATIONS

The present application is a continuation application of International Patent Application No. PCT/JP2019/036348 filed on Sep. 17, 2019, which designated the U.S. and claims the benefit of priority from Japanese Patent Application No. 2018-177404 filed on Sep. 21, 2018. The entire disclosures of all of the above applications are incorporated herein by reference.

### TECHNICAL FIELD

The present disclosure relates to a battery monitoring device that monitors an assembled battery having a plurality of battery cells connected in series.

### BACKGROUND

A battery monitoring device for monitoring the state of the assembled battery is configured to detect voltages of battery cells through multiple detection lines connected to both terminals of the multiple battery cells. In regard to such a battery monitoring device, conventionally, various configurations for detecting abnormalities such as a connection failure of the detection line have been proposed. Further, the battery monitoring device is provided with a short-circuit switch for short-circuiting a pair of detection lines connected to both terminals of each battery cell in order to execute an equalization process for equalizing the voltage of each battery cell. For example, a battery monitoring device may be configured to detect an abnormality in a detection line based on a change in voltages of a battery cell detected when a short-circuit switch is turned on and off.

### SUMMARY

The present disclosure provides a battery monitoring device that detects an abnormality in a detection line in a short diagnosis time.

### BRIEF DESCRIPTION OF DRAWINGS

Objects, features and advantages of the present disclosure will become more apparent from the following detailed description made with reference to the accompanying drawings, in which:

FIG. 1 is a diagram schematically showing a configuration of a battery monitoring device according to a first embodiment of the present disclosure;

FIG. 2 is a diagram for explaining the operation of each part in an abnormality determination process according to the first embodiment;

FIG. 3 is a time chart showing an operation state and a voltage of each part, when the abnormality determination process is executed in a normal state, according to the first embodiment;

FIG. 4 is a time chart showing an operation state and a voltage of each part, when the abnormality determination process is executed in an abnormal state, according to the first embodiment;

FIG. 5 is a diagram for explaining, as a first part, an operation of each part in an abnormality determination process according to a comparative example;

FIG. 6 is a diagram for explaining, as a second part, the operation of each part in the abnormality determination process according to the comparative example;

FIG. 7 is a time chart showing an operation state and a voltage of each part, when the abnormality determination process is executed in a normal state, according to the comparative example;

FIG. 8 is a time chart showing an operation state and a voltage of each part, when the abnormality determination process is executed in an abnormal state, according to the comparative example;

FIG. 9 is a time chart showing an operation state and a voltage of each part, when an abnormality determination process is executed in a normal state, according to a second embodiment of the present disclosure;

FIG. 10 is a time chart showing an operation state and a voltage of each part, when the abnormality determination process is executed in an abnormal state, according to the second embodiment;

FIG. 11 is a time chart showing an operation state and a voltage of each part, when an abnormality determination process is executed in an normal state, according to a modification of the second embodiment;

FIG. 12 is a time chart showing an operation state and a voltage of each part, when the abnormality determination process is executed in an abnormal state, according to the modification of the second embodiment;

FIG. 13 is a time chart showing an operation state and a voltage of each part, when an abnormality determination process is executed in a normal state, according to a third embodiment of the present disclosure;

FIG. 14 is a time chart showing an operation state and a voltage of each part, when the abnormality determination process is executed in an abnormal state, according to the third embodiment;

FIG. 15 is a time chart showing the voltage of each part when noise is superimposed only on the detection value of one battery cell in the normal state according to the third embodiment;

FIG. 16 is a time chart showing the voltage of each part when common mode noise is superimposed on the detection values of two battery cells in the normal state according to the third embodiment;

FIG. 17 is a time chart showing the voltage of each part when differential mode noise is superimposed on the detection values of the two battery cells in the normal state according to the third embodiment;

FIG. 18 is a schematic diagram showing a configuration of a battery monitoring device according to a fourth embodiment;

FIG. 19 is a time chart showing an operation state and a voltage of each part, when an abnormality determination process is executed in a normal state, according to a fourth embodiment of the present disclosure; and

FIG. 20 is a time chart showing an operation state and a voltage of each part, when the abnormality determination process is executed in an abnormal state, according to the fourth embodiment.

### DETAILED DESCRIPTION

In a battery monitoring device, an abnormality in a detection line may be detected using the behavior of a detection voltage of a predetermined battery cell when the short-circuit switch corresponding to the predetermined battery cell is operated, and the behavior of a detection voltage of the predetermined battery cell when another short-circuit switch corresponding to another battery cell adjacent to the predetermined battery cell is operated. However, such a detection method needs a two-step operation of operating the short-circuit switch corresponding to the predetermined battery cell and operating the short-circuit switch corresponding to another battery cell adjacent to the predetermined battery cell. As a result, the time to detect an abnormality, that is, a diagnosis time is likely to be prolonged.

According to an aspect of the present disclosure, a battery monitoring device is configured to monitor an assembled battery in which a plurality of battery cells are connected in series. The battery monitoring device includes: a plurality of detection lines, a voltage detection circuit, a plurality of filters, and a plurality of short-circuit switches. The detection lines are connected to both terminals of the respective battery cells. The voltage detection circuit is configured to detect voltages of the respective battery cells through the detection lines. The filters are correspondingly provided for the battery cells, and disposed between the detection lines and the voltage detection circuit. The short-circuit switches are correspondingly provided for the battery cells, and each configured to short-circuit a corresponding pair of detection lines connected to the both terminals of the corresponding battery cell.

As described above, the battery monitoring device has a configuration included in a general battery monitoring device. The battery monitoring device further includes an abnormality determination circuit that controls to turn on and off the plurality of short-circuit switches and determines whether or not an abnormality has occurred in the detection lines. In such a configuration, of the adjacent battery cells, one may be referred to as a first battery cell, and another may be referred to as a second battery cell. The short-circuit switch corresponding to the first battery cell may be referred to as a first switch, and the short-circuit switch corresponding to the second battery cell may be referred to as a second switch. The abnormality determination circuit determines an abnormality of the detection line in the following manner.

Namely, the abnormality determination circuit executes an on and off control in which the second switch is turned from an off state to an on state, and then turned to the off state again, in a state where the first switch is kept in an off state. The abnormality determination circuit detects the voltages of the first battery cell and the voltages of the second battery cell before and after executing the on and off control. The voltages of the first battery cell and the voltages of the second battery cell detected before and after the on and off control show different behavior between a case where the detection lines connected to the both terminals of the first battery cell are in a normal state and a case where the detection lines connected to the both terminals of the first battery cell have an abnormality. Thus, the abnormality determination circuit determines an abnormality of the detection line based on these four voltage values detected.

In such a configuration, an abnormality of the detection lines is determined using not only the voltage values of the first battery cell but also the voltage values of the second battery cell adjacent to the first battery cell. Therefore, the abnormality determination can be performed only by performing the on and off control to the short-circuit switch that corresponds to either of the adjacent battery cells. As such, in the configuration described above, the time to detect an abnormality of the detection lines, that is, the diagnosis time can be shortened.

Hereinafter, multiple embodiments will be described with reference to the drawings. In the respective embodiments, substantially the same configurations are denoted by identical reference numerals, and repetitive description will be omitted.

### First Embodiment

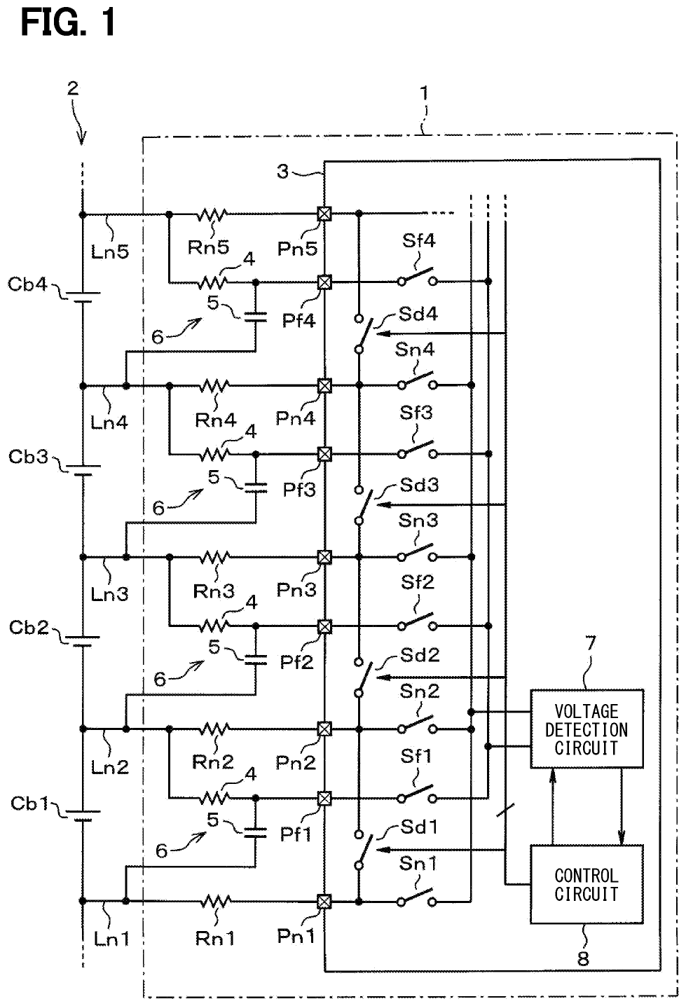

A first embodiment of the present disclosure will be described hereinafter with reference to FIGS. 1 to 6.

A battery monitoring device 1 shown in FIG. 1 is a device to detect various states, such as voltages, of an assembled battery 2 and monitor the state of the assembled battery 2. The assembled battery 2 is, for example, mounted on a vehicle, and has a configuration in which a plurality of battery cells Cb are connected in series in multiple stages. In this case, the battery cell Cb is, for example, a secondary battery such as a lithium ion battery, a fuel cell, or the like. In FIG. 1, four battery cells Cb are shown. In order to distinguish the four battery cells Cb, numbers “1” to “4” are, respectively, added to the end of the reference numerals of the four battery cells Cb. Further, parts of the battery monitoring device 1 that are correspondingly provided for the four battery cells Cb are distinguished by adding a similar number to the end of the respective reference numerals. However, when it is not necessary to distinguish the configurations between the four battery cells Cb, the numbers at the end of the reference numerals are omitted and generically indicated.

The battery monitoring device 1 includes a battery monitoring IC 3. The battery monitoring IC 3 has a connection terminal Pn corresponding to a low potential side terminal of each battery cell Cb, and each connection terminal Pn is connected to the low potential side terminal of a corresponding battery cell Cb via a discharging resistance element Rn and a detection line Ln. For example, a high potential side terminal of a battery cell Cb1 is common to the low potential side terminal of the battery cell Cb2 on an upper stage, that is, on a higher voltage side. Therefore, a connection terminal, a discharging resistance element and a detection line corresponding to the battery cell Cb are, respectively, referred to as the connection terminal Pp, the discharging resistance element Rp and the detection line Lp. In this case, the connection terminal Pp1, the discharging resistance element Rp1 and the detection line Lp1, respectively, correspond to the connection terminal Pn2, the discharging resistance element Rn2, and the detection line Ln2.

Between the high potential side terminal and the low potential side terminal of each battery cell Cb, a series circuit of the resistance element 4 and a capacitor 5 is connected. The resistance element 4 and the capacitor 5 constitute a filter 6, as an RC filter. In the battery monitoring IC 3, filter connection terminals Pf1 to Pf4 are provided between the connection terminals Pn corresponding to the respective battery cells Cb. An output terminal of the filter 6, which is a common connection point between the resistance element 4 and the capacitor 5, is connected to the filter connection terminal Pf. In this way, the filters 6 are correspondingly provided for the battery cells Cb. Further, the filters 6 are connected between the detection lines Ln and the voltage detection circuit 7, which will be described later. Hereinafter, the filter connection terminal Pf will be simply referred to as the connection terminal Pf.

In the present embodiment, the battery monitoring device 1 is provided by the battery monitoring IC 3 and the filters 6 disposed outside the battery monitoring IC 3. The battery monitoring IC 3 includes a plurality of short-circuit switches Sd1 to Sd4, a plurality of selection switches Sf1 to Sf4, a plurality of selection switches Sn1 to Sn4, a voltage detection circuit 7, a control circuit 8, and the like. The short-circuit switch Sd, the selection switch Sf, and the selection switch Sn are each provided by, for example, an N-channel MOSFET.

The short-circuit switches Sd are correspondingly provided for the battery cells Cb. The short-circuit switch Sd is a switch that short-circuits a pair of detection lines Ln connected to both terminals of the battery cell Cb. The short-circuit switch Sd is provided for equalizing variations in cell voltages of the battery cells Cb by short-circuiting the both terminals of the battery cell Cb, which is on the higher voltage side than the other battery cell Cb so as to discharge the battery cell Cb on the higher voltage side. The short-circuit switch Sd corresponding to a predetermined battery cell Cb is connected between the connection terminal Pn that connects to the high potential side terminal of the predetermined battery cell Cb and the connection terminal Pn that connects to the low potential side terminal of the predetermined battery cell Cb. For example, the short-circuit switch Sd1 corresponding to the battery cell Cb1 is connected between the connection terminal Pn1 and the connection terminal Pn2.

The voltage detection circuit 7 detects the voltage of each battery cell Cb via a plurality of detection lines Ln connected to both terminals of each battery cell Cb. The control circuit 8 controls to turn on and off the short-circuit switches Sd, the selection switches Sf, and the selection switches Sn. The control circuit 8 executes various processes described later. In this case, the connection terminal Pn corresponding to each battery cell Cb is connected to one of input terminals of the voltage detection circuit 7 via the selection switch Sn. Further, the connection terminal Pf corresponding to each battery cell Cb is connected to the other of the input terminals of the voltage detection circuit 7 via the selection switch Sf.

The control circuit 8 executes a voltage detection process. In the voltage detection process, the control circuit 8 controls on and off of the selection switches Sf and Sn, and causes the voltage detection circuit 7 to individually detect the voltage of each battery cell Cb. Specifically, when detecting the voltage of a predetermined battery cell Cb, the control circuit 8 turns on the selection switches Sf and Sn corresponding to the predetermined battery cell Cb and turns off the other selection switches Sf and Sn. As a result, the voltage between the both terminals of the predetermined battery cell Cb to be detected is provided to the voltage detection circuit 7, and the cell voltage of the predetermined battery cell Cb is detected by the voltage detection circuit 7.

Further, the control circuit 8 executes an equalization process for equalizing the variation in the cell voltages of the battery cells Cb by controlling on and off of the short-circuit switches Sd. For example, the equalization process is performed in a following manner. That is, when the variation in the cell voltages of the battery cells Cb acquired from the voltage detection circuit 7 is increased, the control circuit 8 determines, among the battery cells Cb, the battery cell Cb having a higher voltage as a discharge target cell to discharge, and calculates the discharge time of the battery cell Cb as the discharge target cell. The control circuit 8 controls on and off of the short-circuit switches Sd so that the short-circuit switch Sd corresponding to the battery cell Cb as the discharge target cell is turned on only for the calculated discharge time. In this way, the equalization of the battery cells Cb is realized.

Further, the control circuit 8 executes an abnormality determination process for determining whether or not an abnormality has occurred in the detection line Ln. Therefore, in the present embodiment, the control circuit 8 corresponds to an abnormality determination unit. The control circuit 8 may also be referred to as an abnormality determination circuit. One of the adjacent battery cells Cb is referred to as a first battery cell, and the other of the adjacent battery cells Cb is referred to as a second battery cell. The short-circuit switch Sd corresponding to the first battery cell is referred to as a first switch, and the short-circuit switch Sd corresponding to the second battery cell Cb is referred to as a second short-circuit switch Sd. In this case, the control circuit 8 executes the abnormality determination process in the following manner.

That is, the control circuit 8 executes an on and off control in which the second switch is turned from an off state to an on state and then turned to the off state again, in a state where the first switch is kept in an off state. The control circuit 8 detects the voltages of the first battery cell and the voltages of the second battery cell before and after executing the on and off control, and determines an abnormality of the detection line Ln based on these four voltage values detected. Specifically, the control circuit 8 determines an abnormality of the detection line Ln based on the difference in the voltages of the first battery cell before and after executing the on and off control and the difference in voltages of the second battery cell before and after executing the on and off control. When the sum of the two differences is larger than a predetermined determination threshold value, the control circuit 8 determines that the detection line Ln has an abnormality.

In the configuration described above, the cell voltage, which is the voltage of the battery cell Cb, is 3 V, for example. In the configuration described above, the resistance value of the discharge resistance element Rn is smaller than the resistance value of the resistance element 4 of the filter 6. Further, the resistance values of the respective discharge resistance elements Rn are designed to be the same as each other.

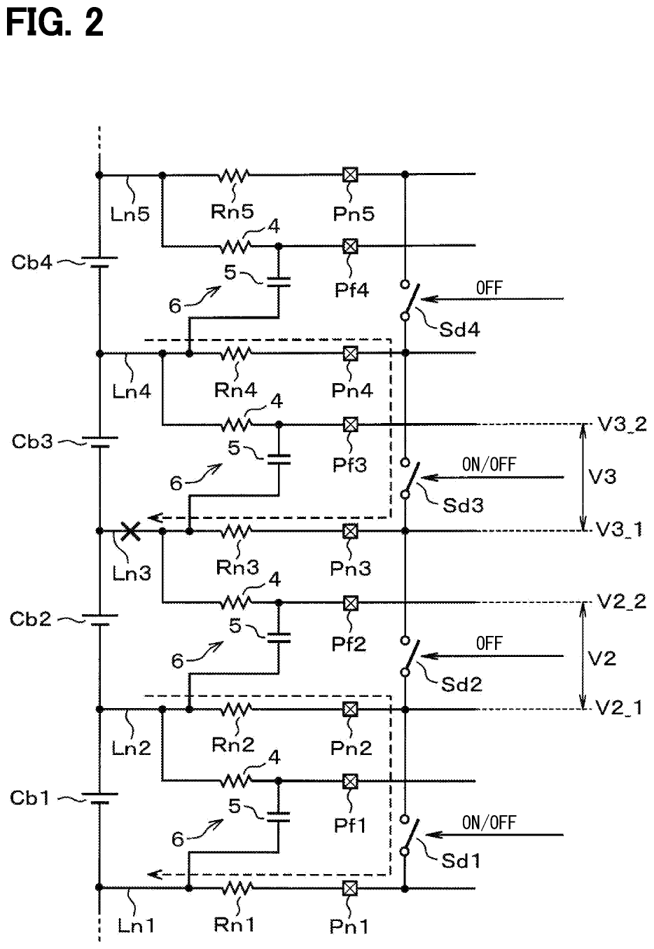

Next, operations of the above-described configuration will be described with reference to FIG. 2 to FIG. 4.

### [1] Details of Abnormality Determination Process

First, an example of specific contents of the abnormality determination process will be described. Here, the contents of the process will be described by taking an abnormality determination for the detection line Ln3 as an example. As shown in FIG. 2, in the abnormality determination process, the control circuit 8 controls the short-circuit switches Sd corresponding to an even-numbered cell group to be turned off, and also controls the short-circuit switches Sd corresponding to an odd-numbered cell group to be turned on and off.

The odd-numbered cell group includes odd-numbered battery cells Cb, among the battery cells Cb, when counted in the order of connection. For example, the odd-numbered cell group includes the battery cells Cb1 and Cb3. The even-numbered cell group includes even-numbered battery cells Cb, among the battery cells Cb, when counted in the order of connection. For example, the even-numbered cell group includes the battery cells Cb2 and Cb4. The connection order may be an incrementing order from the low potential side to the high potential side, or from the high potential side to the low potential side. Further, in the following descriptions, the short-circuit switches Sd corresponding to the odd-numbered cell group will be also referred to as the odd-numbered switches, and the short-circuit switches Sd corresponding to the even-numbered cell group will be also referred to as the even-numbered switches.

In this case, the control circuit 8 controls all the even-numbered switches to be off and all the odd-numbered switches to be turned on and off. However, in a case of determining an abnormality of only the detection line Ln3, the control circuit 8 controls, among the even-numbered switches, at least the short-circuit switches Sd2 and Sd4 to be off and, among the odd-numbered switches, at least the short-circuit switch Sd3 to be turned on and off. That is, in the abnormality determination process, the control circuit 8 controls to turn off the short-circuit switches Sd (for example, Sd2 and Sd4) corresponding to the battery cells Cb (for example, the battery cells Cb2 and Cb4) that are adjacent to the battery cells Cb (for example, the battery cell Cb3) connecting to the detection lines Ln (for example, the detection line Ln3) as a target line to be determined, and to turn on and off the short-circuit switches Sd (for example, Sd3) corresponding to the battery cells Cb connected to the detection lines Ln as the target line to be determined.

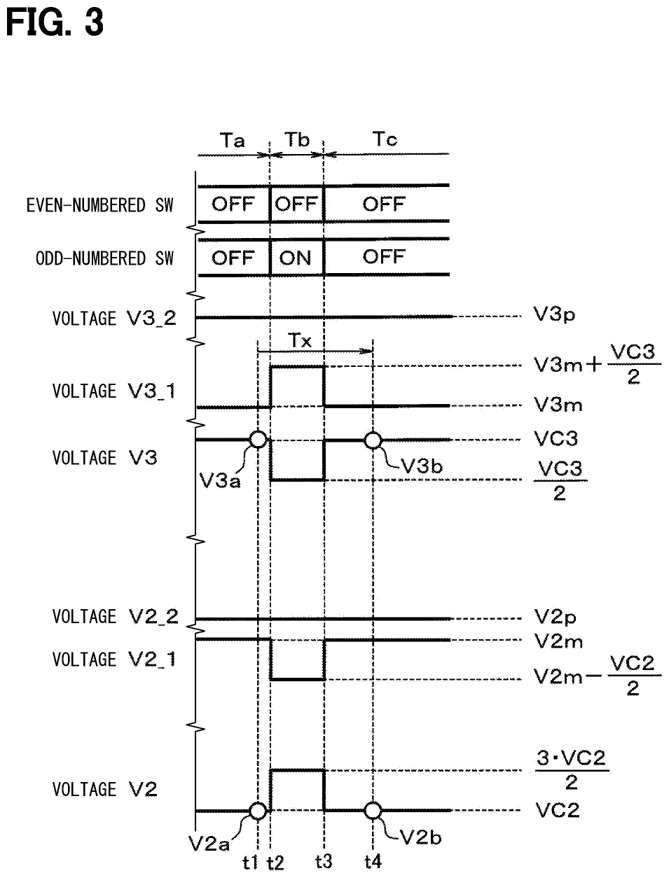

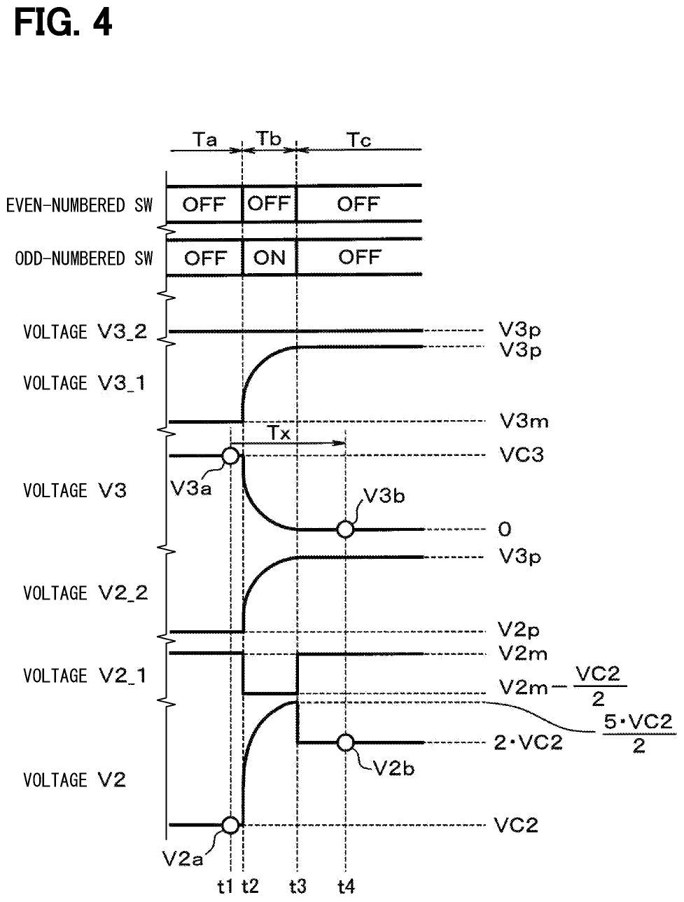

As shown in FIGS. 3 and 4, the even-numbered switches such as short-circuit switches Sd2 and Sd4 are in off states all the time. Further, the odd-numbered switches such as the short-circuit switches Sd1 and Sd3 are in off states in a period Ta before the time point t2 and in a period Tc after the time point t3, and are in on states in a period Tb from the time point t2 to the time point t3. The control circuit 8 detects the voltages of the battery cells Cb2 and the battery cells Cb3 at an arbitrary time point t1 in the period Ta before the on and off control of the odd-numbered switches. Further, the control circuit 8 detects the voltages of the battery cells Cb2 and the battery cells Cb3 at an arbitrary time point t4 in the period Tc after the on and off control of the odd-numbered switches.

The control circuit 8 determines an abnormality of the detection line Ln based on the four detected voltage values. Specifically, the control circuit 8 determines an abnormality of the detection line Ln based on the abnormality determination formula shown in the following expression (1). In this case, V2a and V3a, respectively, represent the voltage values of the battery cells Cb2 and Cb3 detected at the time point t1, and V2b and V3b, respectively, represents the voltage values of the battery cells Cb2 and Cb3 detected at the time point t4. Also, Th represents a determination threshold.

|V3a−V3b|+|V2a−V2b″>Th (1)

The control circuit 8 determines that an abnormality has occurred in the detection line Ln, when the relation in the above expression (1) is satisfied. The control circuit 8 determines that no abnormality has occurred in the detection line Ln and the detection line Ln is normal, when the relation in the above expression (1) is not satisfied. That is, when the sum of the absolute value of the difference between the voltage V3a and the voltage V3b and the absolute value of the difference between the voltage V2a and the voltage V2b is larger than the determination threshold value Th, the control circuit 8 determines that an abnormality has occurred in the detection line Ln. Further, when the sum is equal to or less than the determination threshold value Th, the control circuit 8 determines that the detection line Ln is in a normal state. In the present embodiment, the determination threshold value Th is set to, for example, “0”.

Operation related to abnormality determination process in normal state As shown in FIG. 3, in a normal state in which the detection line Ln3 is not disconnected, the voltage V3_2 of the connection terminal Pf3 keeps a voltage V3p corresponding to the potential of the high potential side terminal of the battery cell Cb3 throughout the periods Ta, Tb and Tc. On the other hand, the voltage V3_1 of the connection terminal Pn3 is a voltage V3m corresponding to the potential of the low potential side terminal of the battery cell Cb3 in the period Ta in the normal state. Therefore, in the normal state, the voltage V3 between the connection terminal Pf3 and the connection terminal Pn3 in the period Ta, that is, the detection value of the voltage of the battery cell Cb3 is a voltage VC3 (for example, 3V) corresponding to the voltage of the battery cell Cb3. As such, the voltage V3a, which is the detection value of the voltage of the battery cell Cb3 at the time point t1, is the voltage VC3.

Further, in the normal state, the voltage V2_2 of the connection terminal Pf2 keeps a voltage V2p corresponding to the voltage of the high potential side terminal of the battery cell Cb2 throughout the periods Ta, Tb and Tc. On the other hand, the voltage V2_1 of the connection terminal Pn2 is a voltage V2m corresponding to the potential of the low potential side terminal of the battery cell Cb2 in the period Ta in the normal state. Therefore, in the normal state, the voltage V2 between the connection terminal Pf2 and the connection terminal Pn2 in the period Ta, that is, the detection value of the voltage of the battery cell Cb2 is a voltage VC2 (for example, 3V) corresponding to the voltage of the battery cell Cb2. As such, the voltage V2a, which is the detection value of the voltage of the battery cell Cb2 at the time point t1, is the voltage VC2.

In the normal state, when the odd-numbered switch is turned on at the time point t2, as shown by the broken line arrow in FIG. 2, a current flows through a path that short-circuits both terminals of the battery cell Cb3 via the discharge resistance elements Rn3 and Rn4. As a result of such a current flowing, in the period Tb in the normal state, the voltage obtained by dividing the voltage of the battery cell Cb3 by the two discharge resistance elements Rn3 and Rn4, which have the same resistance value, appears at the connection terminal Pn3. Therefore, in the period Tb in the normal state, the voltage V3_1 of the connection terminal Pn3 becomes a voltage (=V3m+VC3/2) which is higher than the voltage V3m by about ½ of the voltage VC3. Therefore, the voltage V3 in the period Tb of the normal state is a voltage VC3/2 (for example, 1.5V) which is about ½ of the voltage VC3 of the battery cell Cb3.

In this case, when the odd-numbered switch is turned off at the time point t3, the voltage of the connection terminal Pn3 changes sharply toward the voltage V3m. Therefore, in the period Tc in the normal state, the voltage V3_1 of the connection terminal Pn3 becomes the voltage V3m. For this reason, the voltage V3 in the period Tc in the normal state is the voltage VC3 (for example, 3V) corresponding to the voltage of the battery cell Cb3. Therefore, the voltage V3b, which is the detection value of the voltage of the battery cell Cb3 at the time point t4, is the voltage VC3.

In the normal state, when the odd-numbered switch is turned on at the time point t2, as shown by the broken line arrow in FIG. 2, a current flows through a path that short-circuits both terminals of the battery cell Cb1 via the discharge resistance elements Rn1 and Rn2. As a result of such a current flowing, in the period Tb in the normal state, a voltage obtained by dividing the voltage of the battery cell Cb1 by two discharge resistance elements Rn1 and Rn2, which have the same resistance value, appears at the connection terminal Pn2. Therefore, in the period Tb in the normal state, the voltage V2_1 of the connection terminal Pn2 becomes a voltage (=V2m−VC2/2) which is lower than the voltage V2m by about ½ of the voltage VC2. As such, the voltage V2 in the period Tb in the normal state is a voltage of 3·VC2/2 (for example, 4.5V), which is about 3/2 of the voltage VC2 of the battery cell Cb2.

In this case, when the odd-numbered switch is turned off at the time point t3, the voltage of the connection terminal Pn2 changes sharply toward the voltage V2m. Therefore, in the period Tc in the normal state, the voltage V2_1 of the connection terminal Pn2 becomes the voltage V2m. For this reason, the voltage V2 in the period Tc in the normal state is the voltage VC2 (for example, 3V) corresponding to the voltage of the battery cell Cb2. As such, the voltage V2b, which is the detection value of the voltage of the battery cell Cb2 at the time point t4, is the voltage VC2.

As described above, in the normal state, the voltage V3a, which is the detection value of the voltage of the battery cell Cb3 at the time point t1, and the voltage V3b, which is the detection value of the voltage of the battery cell Cb3 at the time point t4, are both voltage VC3 (for example, 3V). Further, in the normal state, the voltage V2a, which is the detection value of the voltage of the battery cell Cb2 at the time point t1, and the voltage V2b, which is the detection value of the voltage of the battery cell Cb2 at the time point t4, are both voltage VC2 (for example, 3V). For this reason, when each of these detection values is substituted into the above expression (1), the left side of the above expression (1) is 0, and the above expression (1) does not hold. As such, in the normal state, as a result of the abnormality determination process, the result that the detection line Ln3 is normal is obtained.

[3] Operation related to abnormality determination process in abnormal state

As shown in FIG. 4, in an abnormal state in which the detection line Ln3 is disconnected, the voltage V3_2 of the connection terminal Pf3 is the voltage V3p throughout the periods Ta, Tb, and Tc, as in the normal state. In FIG. 2, the position of the disconnection on the detection line Ln3 is indicated by a cross. Further, the voltage V3_1 of the connection terminal Pn3 is a voltage V3m in the period Ta in the abnormal state, as in the period Ta in the normal state. For this reason, the voltage V3 in the period Ta in the abnormal state is the voltage VC3 (for example, 3V), similarly to that in the period Ta in the normal state. Therefore, the voltage V3a, which is the detection value of the voltage of the battery cell Cb3 at the time point t1, is the voltage VC3.

Further, in the abnormal state, the voltage V2_2 of the connection terminal Pf2 is the voltage V2p throughout the periods Ta, Tb and Tc, as in the normal state. In the period Ta in the abnormal state, the voltage V2_1 of the connection terminal Pn2 is a voltage V2m, as in the normal period Ta. For this reason, the voltage V2 in the period Ta in the abnormal state is the voltage VC2 (for example, 3V), as in the period Ta in the normal state. Therefore, the voltage V2a, which is the detection value of the voltage of the battery cell Cb2 at the time point t1, is the voltage VC2.

In the abnormal state, when the odd-numbered switch is turned on at the time point t2, the current indicated by the broken line arrow in FIG. 2 does not flow, and the voltage V3_1 of the connection terminal Pn3 changes toward the voltage V3p corresponding to the potential of the high potential side terminal of the battery cell Cb3. At this time, since the capacitor 5 of the filter 6 corresponding to the battery cell Cb2 is charged, the slope of the change of the voltage V3_1 becomes relatively gentle. For this reason, in the period Tb in the abnormal state, the voltage V3_1 of the connection terminal Pn3 changes from the voltage V3m toward the voltage V3p. Therefore, the voltage V3 in the period Tb in the abnormal state changes from the voltage VC3 of the battery cell Cb3 toward 0 V.

In this case, even if the odd-numbered switch is turned off at the time point t3, since the detection line Ln3 is disconnected, the voltage V3_1 of the connection terminal Pn3 does not change toward the voltage V3m and is kept to a voltage close to the voltage V3p. As a result, the voltage V3 in the period Tc in the abnormal state is 0V. Therefore, the voltage V3b, which is the detection value of the voltage of the battery cell Cb3 at the time point t4, is 0V.

In the abnormal state, when the odd-numbered switch is turned on at the time point t2, the current indicated by the broken line arrow in FIG. 2 does not flow, and the voltage V2_2 of the connection terminal Pf2 changes toward the voltage V3p, similarly to the voltage V3_1 of the connection terminal Pn3. Therefore, in the period Tb in the abnormal state, the voltage V2_2 of the connection terminal Pf2 changes from the voltage V2p toward the voltage V3p.

In the abnormal state, when the odd-numbered switch is turned on at the time point t2, a current flows through a path that short-circuits both terminals of the battery cell Cb1 via the discharge resistance elements Rn1 and Rn2, as in the normal state. Therefore, in the period Tb in the abnormal state, the voltage V2_1 of the connection terminal Pn2 becomes a voltage (=V2m−VC2/2) which is lower than the voltage V2m by about ½ of the voltage VC2, as in the period Tb in the normal state. Therefore, assuming that the voltage VC2 and the voltage VC3 have the same voltage value, the voltage V2 in the period Tb in the abnormal state changes from the voltage VC2 toward a voltage which is about 5/2 of the voltage VC2 (for example, 7.5 V).

In this case, even if the odd-numbered switch is turned off at the time point t3, since the detection line Ln3 is disconnected, the voltage V2_2 of the connection terminal Pf2 does not change toward the voltage V2p and is kept to a voltage close to the voltage V3p. Further, in this case, when the odd number switch is turned off at the time point t3, the voltage of the connection terminal Pn2 changes sharply toward the voltage V2m. Therefore, in the period Tc in the abnormal state, the voltage V2_1 of the connection terminal Pn2 becomes the voltage V2m. For this reason, the voltage V2 in the period Tc in the abnormal state becomes a voltage of 2·VC2 (for example, 6 V) which is about twice the voltage VC2. Therefore, the voltage V2b, which is the detection value of the voltage of the battery cell Cb2 at the time point t4, is the voltage 2·VC2.

As described above, in the abnormal state, the voltage V3a which is the detection value of the voltage of the battery cell Cb3 at the time point t1 and the voltage V3b which is the detection value of the voltage of the battery cell Cb3 at the time point t4 are significantly different values. There is a difference by the voltage VC3 of the battery cell Cb3 between the detection values. Further, in the abnormal state, the voltage V2a, which is the detection value of the voltage of the battery cell Cb2 at the time point t1, and the voltage V2b, which is the detection value of the voltage of the battery cell Cb2 at the time point t4, are significantly different values. There is a difference by the voltage VC2 of the battery cell Cb2 between the detection values. Therefore, when each of these detection values is substituted into the above expression (1), the left side of the above expression (1) becomes a value of about twice the cell voltage, and the above expression (1) is satisfied. AS such, in the abnormal state, as a result of the abnormality determination process, the result that the detection line Ln3 has the abnormality is obtained.

As described above, in the abnormality determination process of the present embodiment, the abnormality of the detection line Ln is determined using not only the voltage value of the first battery cell, which is one of the adjacent battery cells Cb, but also the voltage value of the second battery cell, which is the battery cell Cb adjacent to the first battery cell. In this way, as described above, the abnormality determination can be executed only by performing the on and off control of the short-circuit switch Sd provided corresponding to one of the adjacent battery cells Cb. Therefore, according to the present embodiment, it is possible to attain an excellent effect that the time for detecting the abnormality of the detection line Ln, that is, the diagnosis time can be shortened.

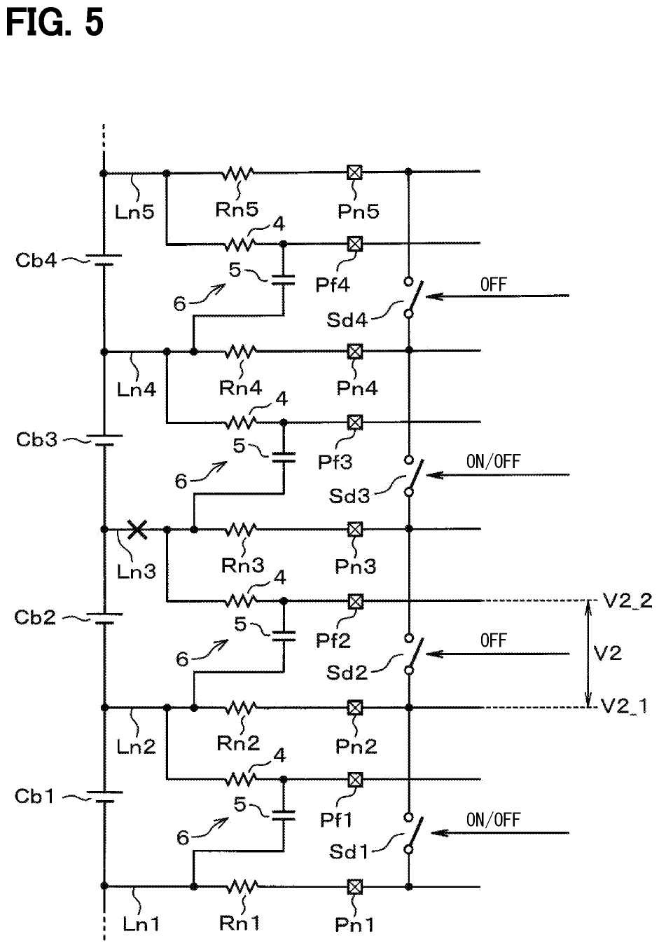

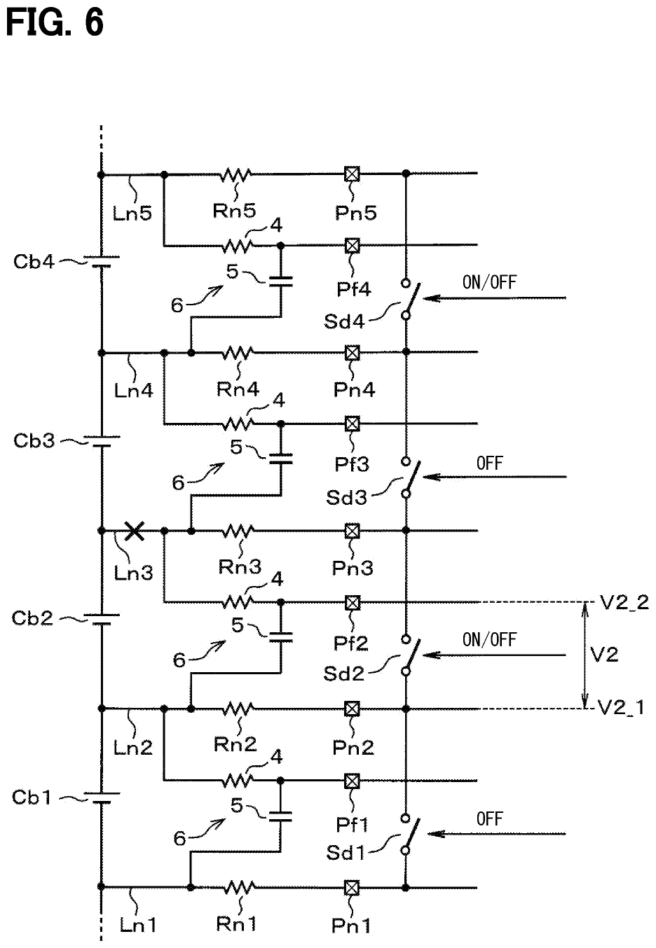

The effect achieved by the present embodiment will be described in more detail in comparison with a comparative example shown in FIG. 5. In an abnormality determination process of the comparative example, as shown in FIG. 5, the control circuit 8 controls the even-numbered switch to be off and the odd-numbered switch to be turned on and off. Thereafter, as shown in FIG. 6, the control circuit 8 controls the odd-numbered switch to be off, and the even-numbered switch to be turned on and off.

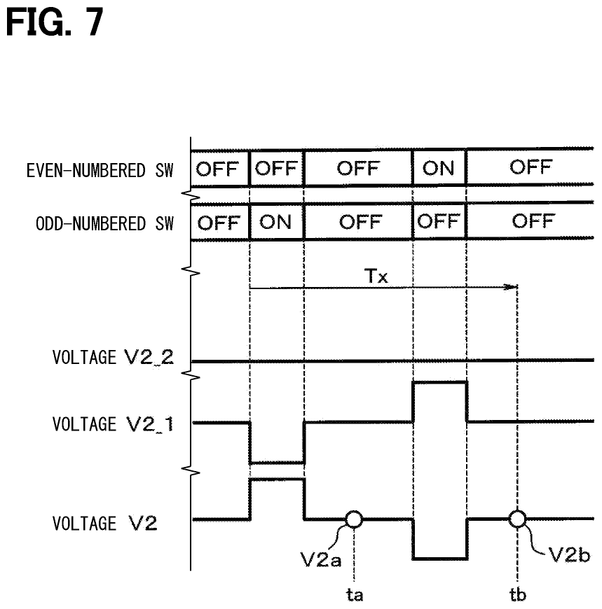

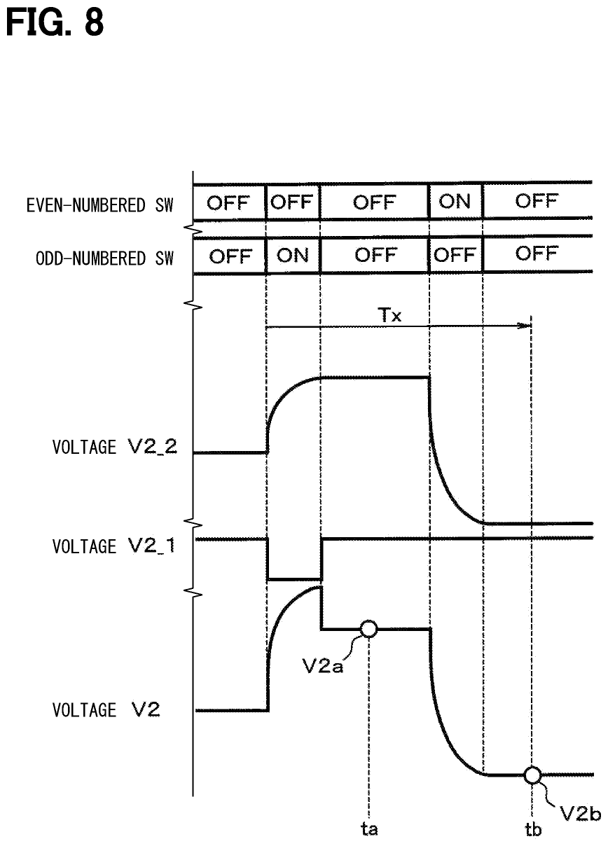

In this case, as shown in FIGS. 7 and 8, the control circuit 8 detects the voltage of the battery cell Cb2 at an arbitrary time point ta after the on and off control of the odd-numbered switch. Also, the control circuit 8 detects the voltage of the battery cell Cb2 at an arbitrary time point tb after the on and off control of the even-numbered switch. The control circuit 8 determines an abnormality of the detection line Ln based on the two detected voltage values. Specifically, the control circuit 8 determines the abnormality of the detection line Ln based on an abnormality determination formula shown by the following expression (2). In this case, V2a represents the voltage of the battery cell Cb2 detected at the time point ta, and V2b represents the voltage of the battery cell Cb2 detected at the time point tb. Also, Th represents a determination threshold value.

|Va2−V2b|>Th (2)

The control circuit 8 determines that an abnormality has occurred in the detection line Ln when the above expression (2) is satisfied. The control circuit 8 determines that the detection line Ln is in a normal state when the above expression (2) is not satisfied. Even in such a comparative example, as shown in FIG. 7, when the detection line Ln3 is in a normal state without disconnection, the voltage V2a and the voltage V2b have the same value. As a result, the determination result that the detection line Ln3 is in a normal state is obtained. Further, even in such a comparative example, as shown in FIG. 8, in an abnormal state in which the detection line Ln3 is disconnected, the voltage V2a and the voltage V2b have significantly different values. As a result, the determination result that the detection line Ln3 is in the abnormal state is obtained.

In the abnormality determination process of the comparative example, however, the determination is made after both the odd-numbered switch and the even-numbered switch are alternately subjected to the on and off control. As a result, the time required to detect the abnormality of the detection line Ln, that is, the diagnosis time Tx is a relatively long time. On the other hand, in the abnormality determination process of the present embodiment, the abnormality determination can be made only by subjecting one of the odd-numbered switch and the even-numbered switch to the on and off control. In the present embodiment, therefore, the diagnosis time Tx shown in FIGS. 3 and 4 is reduced to a short time, which is about half of the diagnosis time Tx of the comparative examples shown in FIGS. 7 and 8. According to the present embodiment, as described above, it is possible to attain an excellent effect that the diagnosis time for detecting the abnormality of the detection line Ln can be significantly shortened as compared with the comparative example.

In the abnormality determination process of the present embodiment, the control circuit 8 controls all the odd-numbered switches to be turned on and off in the state where all the even-numbered switches are controlled to be off, and determines the abnormality of the detection line Ln based on the voltage values of the battery cell Cb before and after the on and off control of the odd-numbered switches is executed. In this case, it is possible to determine abnormalities of the detection lines Ln connected to the low potential side terminals of all the battery cells Cb of the odd-numbered cell group by performing the above-described operational control once. In the abnormality determination process of the present embodiment described above, if the control of the even-numbered switch and the odd-numbered switch is reversed, it is possible to determine abnormalities of the detection lines Ln connected to the low potential side terminals of all the battery cells Cb of the even-numbered cell group by performing the above-described operational control once.

### Second Embodiment

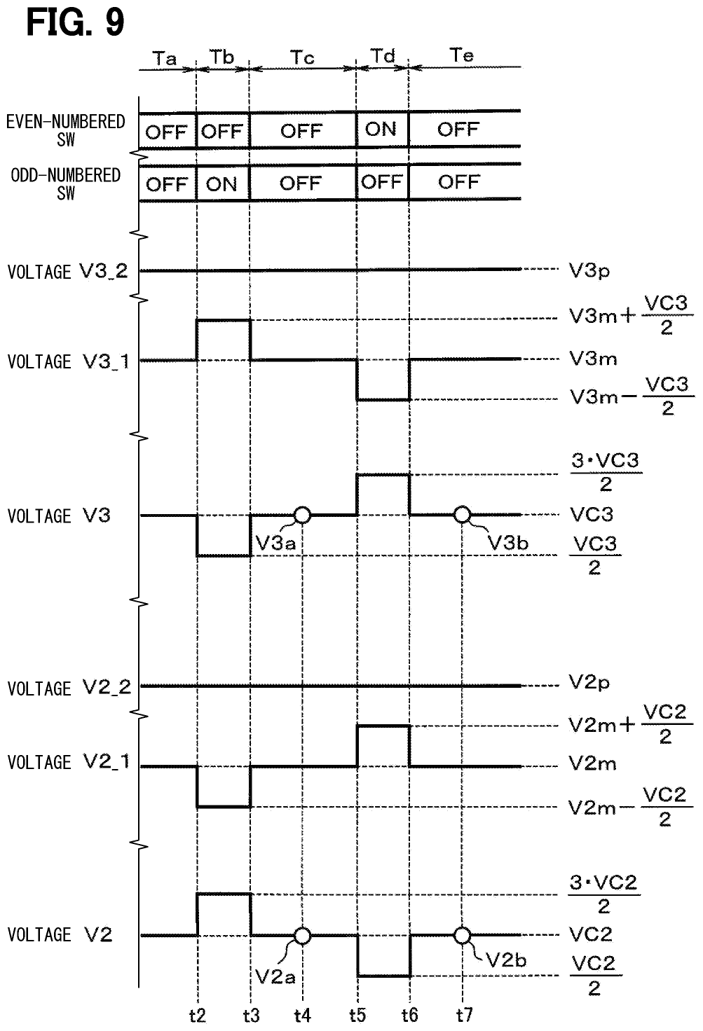

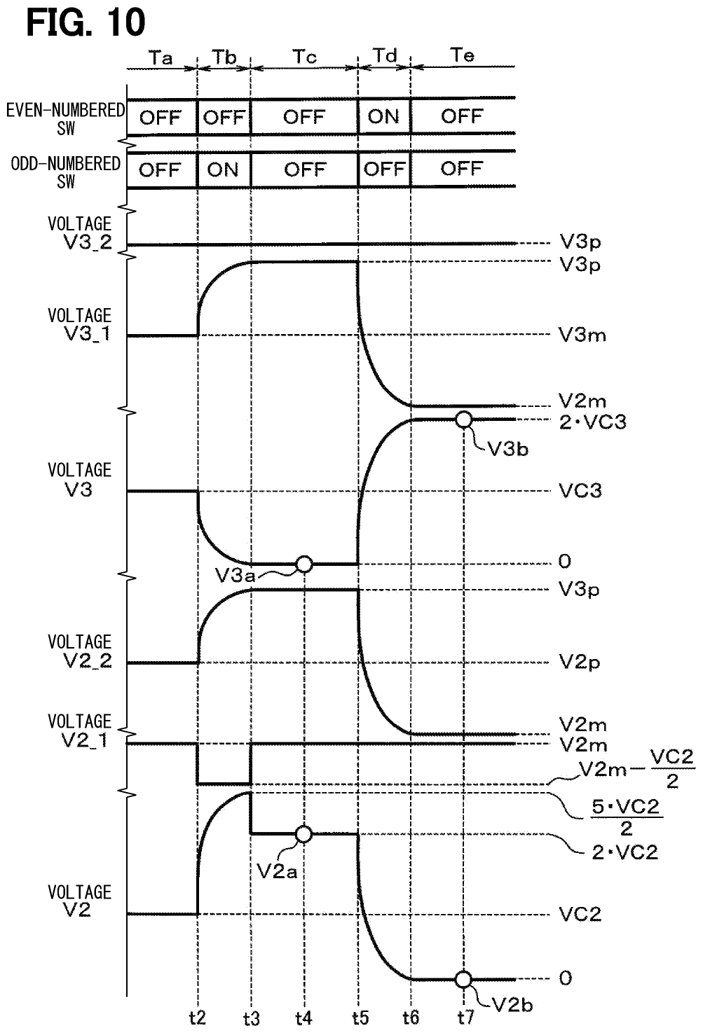

A second embodiment will hereinafter be described with reference to FIGS. 9 and 10.

In the second embodiment, the specific content of the abnormality determination process by the control circuit 8 is different from that in the first embodiment. Since the configurations are the same as those of the first embodiment, the present embodiment will be described also with reference to FIG. 1 and the like.

In the present embodiment, the control circuit 8 executes an on and off control in which the second switch is turned from an off state to an on state, and then turned to the off state again in a state where the first switch is kept in an off state, similarly to the first embodiment. However, the control circuit 8 executes an on and off control in which the first switch is turned from an off state to an on state and then turned to the off state again in the state where the second switch is kept in an off state, prior to the execution of the on and off control of the second switch in the state of the first switch being kept in the off state.

### [1] Details of Abnormality Determination Process

Hereinafter, the content of the abnormality determination process of the present embodiment will be described by taking an abnormality determination for the detection line Ln3 as an example. In the abnormality determination process, the control circuit 8 controls the even-numbered switch to be off and the odd-numbered switch to be turned on and off, and then controls the odd-numbered switch to be off and the even-numbered switch to be turned on and off.

In this case, the control circuit 8 controls all the even-numbered switches to be off and all the odd-numbered switches to be turned on and off. However, if only the abnormality of the detection line Ln3 is determined, at least the short-circuit switches Sd2 and Sd4, among the even-numbered switches, may be controlled to be off, and at least the short-circuit switch Sd3, among the odd-numbered switches, may be controlled to be turned on and off. In this case, the control circuit 8 controls all the odd-numbered switches to be off and all the even-numbered switches to be turned on and off. However, if only the abnormality of the detection line Ln3 is determined, at least the short-circuit switch Sd3, among the odd-numbered switches, may be controlled to be turned off, and at least the short-circuit switches Sd2 and Sd4, among the even-numbered switches, may be controlled to be turned on and off.

That is, in the abnormality determination process, the control circuit 8 controls the short-circuit switch Sd (for example, Sd2 and Sd4) corresponding to the battery cell Cb adjacent to the battery cell Cb connected to the detection line Ln (for example, detection line Ln3) as the target line to be determined to be turned off, and controls the short-circuit switch Sd (for example, Sd3) corresponding to the battery cell Cb connected to the detection line Ln as the target line to be determined to be turned on and off. Further, in the abnormality determination process, the control circuit 8 controls the short-circuit switch Sd (for example, Sd3) corresponding to the battery cell Cb connected to the detection line Ln as the target line to be determined to be turned off, and controls the short circuit switch Sd (for example, Sd2 and Sd4) corresponding to the battery cell Cb adjacent to the battery cell Cn connected to the detection line Ln as the target line to be determined to be turned on and off.

As shown in FIGS. 9 and 10, the even-numbered switches, such as the short-circuit switches Sd2 and Sd4, are in on states in a period Td from the time point t5 to the time point t6 and in off states in the other periods Ta, Tb, Tc and Te. Further, the odd-numbered switches, such as the short-circuit switches Sd1 and Sd3, are in on states in a period Tb from the time point t2 to the time point t3, and are in off states in the other periods Ta, Tc, Td and Te. The control circuit 8 detects the voltages of the battery cells Cb2 and the battery cells Cb3 at an arbitrary time point t4 in the period Tc before the on and off control of the even-numbered switches. Further, the control circuit 8 detects the voltages of the battery cells Cb2 and the battery cells Cb3 at an arbitrary time point t7 in the period Te after the on and off control of the even-numbered switches.

The control circuit 8 determines the abnormality of the detection line Ln based on the four detected voltage values. Specifically, the control circuit 8 determines the abnormality of the detection line Ln based on the abnormality determination formula of the first embodiment indicated by the expression (1). In this case, V2a and V3a, respectively, indicate the voltages of the battery cells Cb2 and Cb3 detected at the time point t4, and V2b and V3b, respectively, indicate the voltages of the battery cells Cb2 and Cb3 detected at the time point t7. Also, Th indicates the determination threshold value. The control circuit 8 determines the abnormality of the detection line Ln according to the success or failure of the expression (1), as in the first embodiment.

### [2] Operation Related to Abnormality Determination Process in Normal State

As shown in FIG. 9, in a normal state in which the detection line Ln3 is not disconnected, each voltage shows the similar behavior to that of the first embodiment shown in FIG. 3 in the periods Ta, Tb and Tc. Therefore, the voltage V3a, which is the detection value of the voltage of the battery cell Cb3 at the time point t4, is the voltage VC3, and the voltage V2a, which is the detection value of the voltage of the battery cell Cb2 at the time point t4, is the voltage VC2.

In the period Td in the normal state, the even-numbered switches are turned on, so the voltage V3_1 and the voltage V3 have similar behaviors to the voltage V2_1 and the voltage V2 in the period Tb in the normal state. Therefore, in the period Td in the normal state, the voltage V3_1 is a voltage (=V3m−VC3/2) which is lower than the voltage V3m by about ½ of the voltage VC3. As such, the voltage V3 in the period Td in the normal state is a voltage 3·VC3/2 (for example, 4.5V) which is about 3/2 of the voltage VC3. In this case, when the even-numbered switch is turned off at the time point t6, the voltage of the connection terminal Pn3 changes sharply toward the voltage V3m, so that the voltage V3_1 becomes the voltage V3m in the period Te in the normal state. For this reason, the voltage V3 in the period Te in the normal state is the voltage VC3 (for example, 3V). Therefore, the voltage V3b, which is the detection value of the voltage of the battery cell Cb3 at the time point t7, is the voltage VC3.

In the period Td in the normal state, since the even-numbered switch is turned on, the voltage V2_1 and the voltage V2 have similar behavior to the voltage V3_1 and the voltage V3 in the period Tb in the normal state. Therefore, in the period Td in the normal state, the voltage V2_1 is a voltage (=V2m+VC2/2) which is higher than the voltage V2m by about ½ of the voltage VC2. As such, the voltage V2 in the period Td in the normal state is a voltage VC2/2 (for example, 1.5V) which is about ½ of the voltage VC2. In this case, when the even-numbered switch is turned off at the time point t6, the voltage of the connection terminal Pn2 changes sharply toward the voltage V2m, so that the voltage V2_1 becomes the voltage V2m in the period Te in the normal state. For this reason, the voltage V2 in the period Te in the normal state is the voltage VC2 (for example, 3V). Therefore, the voltage V2b, which is the detection value of the voltage of the battery cell Cb2 at the time point t7, is the voltage VC2.

As described above, in the normal state, the voltage V3a, which is the detection value of the voltage of the battery cell Cb3 at the time point t4, and the voltage V3b, which is the detection value of the voltage of the battery cell Cb3 at the time point t7, are both voltage VC3 (for example, 3V). Further, in the normal state, the voltage V2a, which is the detection value of the voltage of the battery cell Cb2 at the time point t4, and the voltage V2b, which is the detection value of the voltage of the battery cell Cb2 at the time point t7, are both voltage VC2 (for example, 3V). Therefore, when each of these detection values is substituted into the above expression (1), the left side of the above expression (1) becomes 0, and thus the above expression (1) does not hold. As such, in the normal state, as a result of the abnormality determination process, the result that the detection line Ln3 is normal is obtained.

### [3] Operation Related to Abnormality Determination Process in Abnormal State

As shown in FIG. 10, in an abnormal state in which the detection line Ln3 is disconnected, each voltage shows the similar behavior to that of the first embodiment shown in FIG. 4 in the periods Ta, Tb and Tc. Therefore, the voltage V3a, which is the detection value of the voltage of the battery cell Cb3 at the time point t4, is 0V, and the voltage V2b, which is the detection value of the voltage of the battery cell Cb2 at the time point t4, is the voltage 2·VC2.

In the period Td in the abnormal state, since the even-numbered switch is turned on, the voltage V3_1 changes toward the voltage V2m. Therefore, the voltage V3 in the period Td in the abnormal state changes from 0 V toward the voltage 2·VC3 which is twice the voltage VC3. In this case, even if the even-numbered switch is turned off at the time point t6, the voltage V3_1 of the connection terminal Pn3 does not change toward the voltage V3m and is maintained at a voltage close to the voltage V2m. For this reason, the voltage V3 in the period Te in the abnormal state is the voltage 2·VC3 (for example, 6 V). Therefore, the voltage V3b, which is the detection value of the voltage of the battery cell Cb3 at the time point t7, is the voltage 2·VC3.

In the period Td in the abnormal state, the voltage V2_2 changes toward the voltage V2m, but the voltage V2_1 does not change from the voltage V2m. Therefore, the voltage V2 in the period Td in the abnormal state changes from the voltage 2·VC2 to 0V. In this case, even if the even-numbered switch is turned off at the time point t6, the voltage V2_2 of the connection terminal Pn2 does not change toward the voltage V2p and is maintained at a voltage close to the voltage V2m. Therefore, the voltage V2b, which is the detection value of the voltage of the battery cell Cb2 at the time point t7, is 0 V.

As described above, in the abnormal state, the voltage V3a, which is the detection value of the voltage of the battery cell Cb3 at the time point t4, and the voltage V3b, which is the detection value of the voltage of the battery cell Cb3 at the time point t7, are significantly different values. There is a voltage difference of twice the voltage VC3 between the detection values. Further, in the abnormal state, the voltage V2a, which is the detection value of the voltage of the battery cell Cb2 at the time point t4, and the voltage V2b, which is the detection value of the voltage of the battery cell Cb2 at the time point t7, are significantly different values. There is a voltage difference of twice the voltage VC2 of the battery cell Cb2 between the detection values. Therefore, when each of these detection values is substituted into the above expression (1), the left side of the above expression (1) becomes a value of about four times the cell voltage, and thus the above expression (1) is satisfied. As such, in the abnormal state, as a result of the abnormality determination process, the result that the detection line Ln3 is abnormal is obtained.

Also in the present embodiment described above, the similar effects to those in the first embodiment are achieved. Further, according to the abnormality determination process of the present embodiment, in the abnormal state, the difference between the voltage V3a and the voltage V3b and the difference between the voltage V2a and the voltage V2b are both about twice as large as those of the first embodiment. As such, according to the abnormality determination process of the present embodiment, the value on the left side of the expression (1) in the abnormal state is about twice the value of the left side of the expression (1) in the abnormal state in the abnormality determination process of the first embodiment.

According to the present embodiment, therefore, if the voltage of the battery cell Cb is about the same as that of the first embodiment and the comparative example, the detection sensitivity for detecting the abnormality of the detection line Ln can be improved by about twice. Further, according to the present embodiment, even when the voltage of the battery cell Cb is reduced to about ½ of those of the first embodiment and the comparative example, it is possible to detect the abnormality of the detection line Ln with the detection sensitivity same as those of the first embodiment and the comparative example.

### <Modification of Abnormality Determination Process of the Second Embodiment>

In the abnormality determination process of the second embodiment, the detection sensitivity is improved by about twice by setting the period Tb and the period Td to a time length that sufficiently secures a waiting time for charging and discharging the capacitor 5 of the filter 6. However, if it is not necessary to increase the detection sensitivity by twice, the waiting time of the filter may be optimized, that is, the lengths of the period Tb and the period Td may be optimized so that the required detection sensitivity can be obtained.

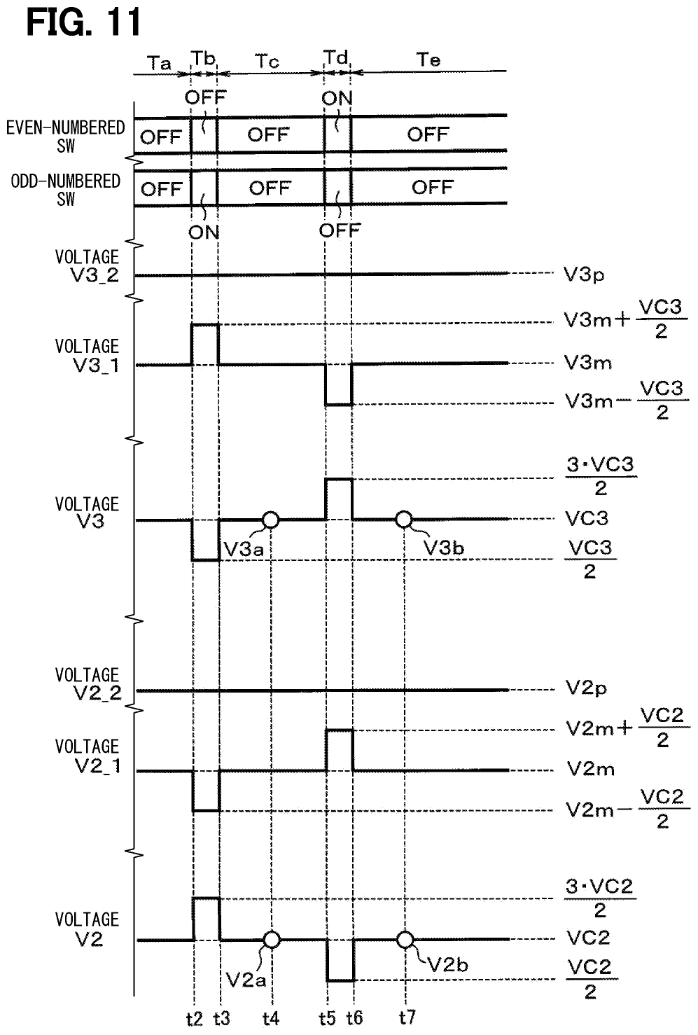

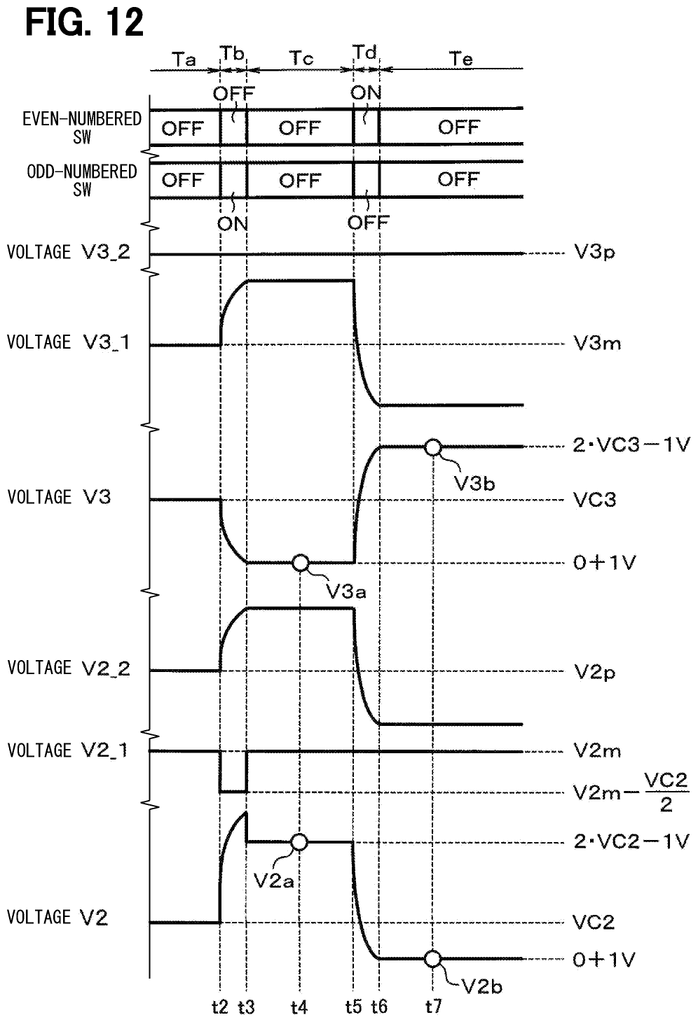

For example, as shown in FIGS. 11 and 12, the lengths of the period Tb and the period Td may be set to about ½ of those in the second embodiment. In the case of such a modification, in the abnormal state, the voltage V3a is a voltage (=0+1V) which is higher than 0 by about 1V, and the voltage V3b is a voltage (=2·VC3−1V) which is lower than the voltage twice the cell voltage by about 1V. Further, the voltage V2a is a voltage (=2·VC2−1V) which is lower than the voltage twice the cell voltage by about 1V, and the voltage V2b is a voltage (=0+1V) which is about 1V higher than 0. Therefore, when each of these detection values is substituted into the above expression (1), the left side of the above expression (1) becomes a value of about 8 V. Therefore, according to the modification, the detection sensitivity can be improved as compared with the first embodiment and the comparative example, and the diagnosis time can be shortened as compared with the comparative example.

### Third Embodiment

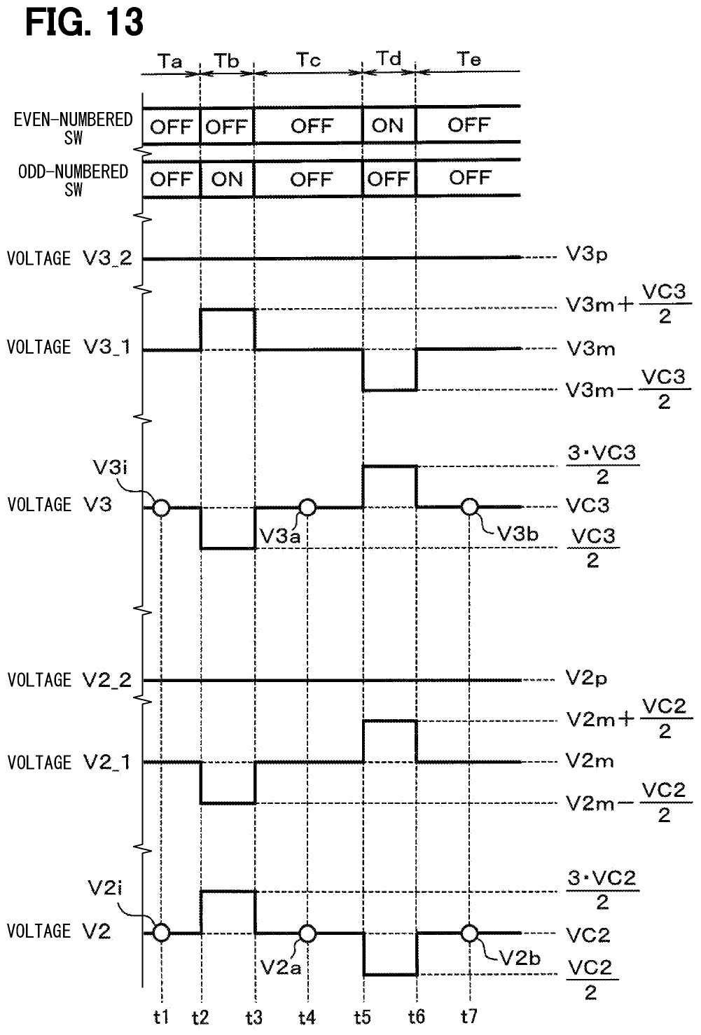

Hereinafter, a third embodiment will be described with reference to FIGS. 13 to 17.

In the third embodiment, the specific content of the abnormality determination process executed by the control circuit 8 is different from each of the above-described embodiments. Since the configurations are the same as those of the first embodiment, the present embodiment will be described also with reference to FIG. 1 and the like.

In the present embodiment, the control circuit 8 controls each short-circuit switch Sd, in the similar manner to the second embodiment. However, in the present embodiment, the control circuit 8 determines an abnormality of the detection line Ln based on a difference between the voltage of the first battery cell and the voltage of the second battery cell before the on and off control is executed, and the voltage of the first battery cell and the voltage of the second battery cell after the on and off control is executed.

### [1] Details of Abnormality Determination Process

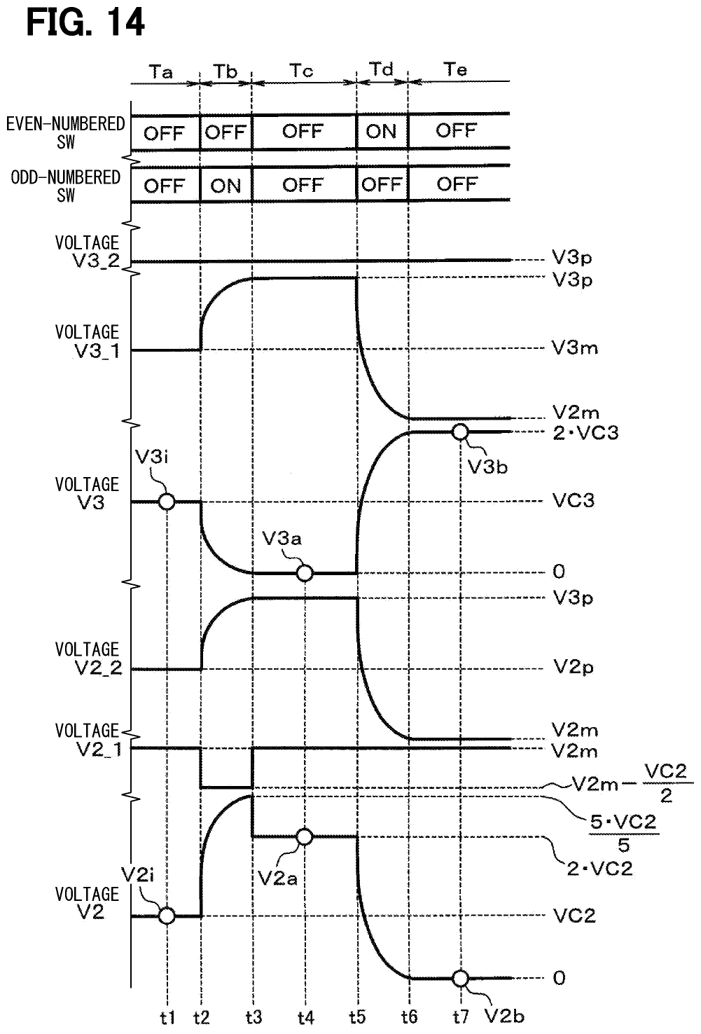

Hereinafter, the content of the abnormality determination process of the present embodiment will be described by taking an abnormality determination for the detection line Ln3 as an example. In the abnormality determination process, the control circuit 8 controls the operation of the even-numbered switch and the odd-numbered switch, similarly to the second embodiment. As shown in FIGS. 13 and 14, the control circuit 8 detects the voltages of the battery cells Cb2 and the battery cells Cb3 at an arbitrary time point t1 in the period Ta before the on and off control of the odd-numbered switch. Further, the control circuit 8 detects the voltages of the battery cells Cb2 and the battery cells Cb3 at an arbitrary time point t4 in the period Tc before the on and off control of the even-numbered switch. Further, the control circuit 8 detects the voltages of the battery cells Cb2 and the battery cells Cb3 at an arbitrary time point t7 in the period Te after the on and off control of the even-numbered switch.

The control circuit 8 determines the abnormality of the detection line Ln based on the detected six voltage values. Specifically, the control circuit 8 determines the abnormality of the detection line Ln based on an abnormality determination formula shown by the following expression (3). In this case, V2i and V3i represent the voltages of the battery cells Cb2 and Cb3 detected at the time point t1, and V2a and V3a represent the voltages of the battery cells Cb2 and Cb3 detected at the time point t4. Also, V2b and V3b represent the voltages of the battery cells Cb2 and Cb3 detected at the time point t7, and Th represents the determination threshold value.

|(V3i−V3a)−(Vi−V2a)|+|(V3i−V3b)−(V2i−V2b)|>Th (3)

The control circuit 8 determines that an abnormality has occurred in the detection line Ln when the above expression (3) is satisfied, and determines that the detection line Ln is normal when the above (3) is not satisfied. In the present embodiment, the determination threshold value Th is set to, for example, “0”.

### [2] Operation Related to Abnormality Determination Process in Normal State

As shown in FIG. 13, in a normal state in which the detection line Ln3 is not disconnected, each voltage shows the similar behavior to that of the second embodiment shown in FIG. 9. Therefore, in the normal state, the voltage V3i which is the detection value of the voltage of the battery cell Cb3 at the time point t1 is the voltage VC3, and the voltage V2i which is the detection value of the voltage of the battery cell Cb2 at the time point t1 is the voltage VC2.

Further, in the normal state, the voltage V3a which is the detection value of the voltage of the battery cell Cb3 at the time point t4 is the voltage VC3, and the voltage V2a which is the detection value of the voltage of the battery cell Cb2 at the time point t4 is the voltage VC2. Furthermore, in the normal state, the voltage V3b which is the detection value of the voltage of the battery cell Cb3 at the time point t7 is the voltage VC3, and the voltage V2b which is the detection value of the voltage of the battery cell Cb2 at the time point t7 is the voltage VC2.

As described above, in the normal state, the voltage V3i, the voltage V3a and the voltage V3b are all voltage VC3 (for example, 3V). Further, in the normal state, the voltage V2i, the voltage V2a and the voltage V2b are all voltage VC2 (for example, 3V). Therefore, when each of these detection values is substituted into the above expression (3), the left side of the above expression (3) becomes 0, and the above expression (3) does not hold. As such, in the normal state, as a result of the abnormality determination process, the result that the detection line Ln3 is normal is obtained.

### [3] Operation Related to Abnormality Determination Process in Abnormal State

As shown in FIG. 14, in an abnormal state in which the detection line Ln3 is disconnected, each voltage shows the similar behavior to that of the second embodiment shown in FIG. 10. Therefore, in the abnormal state, the voltage V3i, which is the detection value of the voltage of the battery cell Cb3 at the time point t1, is the voltage VC3, and the voltage V2i, which is the detection value of the voltage of the battery cell Cb2 at the time point t1, is the voltage VC2.

In the abnormal state, the voltage V3a, which is the detection value of the voltage of the battery cell Cb3 at the time point t4, is 0V, and the voltage V2a, which is the detection value of the voltage of the battery cell Cb2 at the time point t4, is the voltage 2·VC2. Further, in the abnormal state, the voltage V3b, which is the detection value of the voltage of the battery cell Cb3 at the time point t7, is the voltage 2·VC3, and the voltage V2b, which is the detection value of the voltage of the battery cell Cb2 at the time point t7, is 0 V. When each of these detection values is substituted into the above expression (3), the left side of the above expression (3) becomes a value (for example, 12 V) which is about four times the cell voltage, and the above expression (3) is established. Therefore, in the abnormal state, as a result of the abnormality determination processing, the result that the detection line Ln3 is abnormal is obtained.

As described above, in the abnormality determination process of the present embodiment, the abnormality of the detection line Ln is determined based on the difference between the voltage V2a and the voltage V3a before the on and off control is executed and the difference between the voltage V2b and the voltage V3b after the on and off control is executed. Even with such an abnormality determination process, the present embodiment attains the similar effects to those of the abnormality determination process of the second embodiment.

In this case, however, the left side of the abnormality determination formula is in the form of adding the subtraction results of the voltages of different battery cells Cb, that is, the battery cells Cb2 and Cb3. The voltages of different battery cells may not necessarily have the same voltage value, and if the voltages of the battery cells Cb2 and Cb3 constantly have a large difference, the accuracy of abnormality determination may decrease. In the present embodiment, however, the voltages of the battery cells Cb2 and Cb3 in the period Ta before the on and off control of the odd-numbered switch are detected, and these detected voltages are used as the initial voltage in the calculation by the abnormality determination formula. Therefore, even when there is a difference in the voltages of the battery cells Cb2 and Cb3, the accuracy of abnormality determination can be maintained satisfactorily.

Further, according to the present embodiment, the effect of improving the immunity to noise can be achieved. Hereinafter, such an effect will be described with comparison to the comparative example described in the first embodiment and by presenting a specific numerical example. First, in the present embodiment, the detection sensitivity can be improved to about twice that of the comparative example, as in the second embodiment. Therefore, the determination threshold value of the present embodiment can be twice as much as the determination threshold value of the comparative example. Here, it is assumed that the determination threshold value of the present embodiment is 300 mV and the determination threshold value of the comparative example is 150 mV.

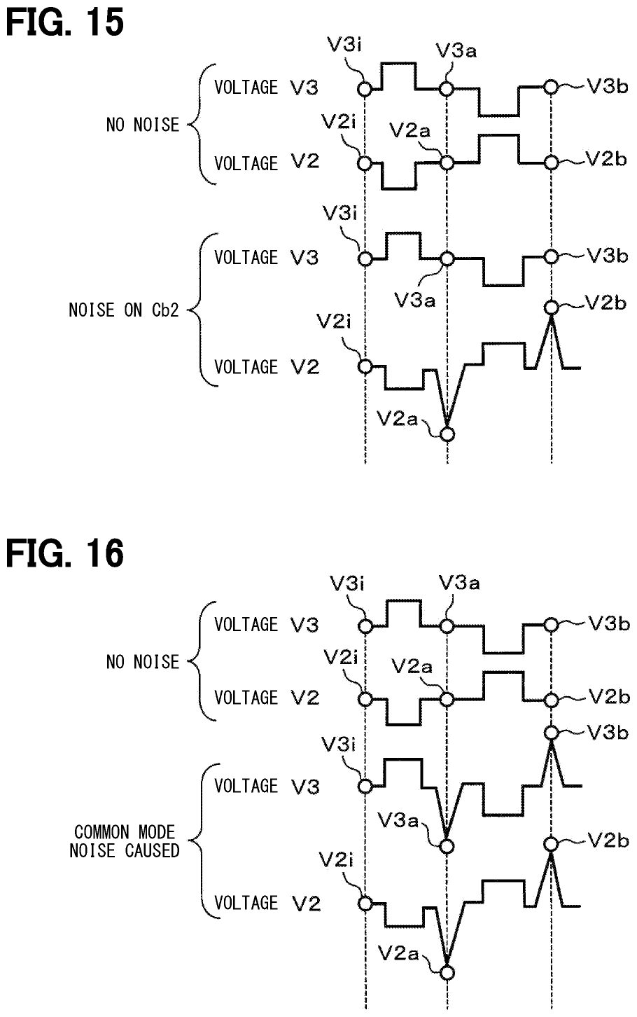

First, as shown in FIG. 15, it is considered a case where noise of 100 mV is superimposed only on the detection values V2a and V2b of the battery cell Cb2. In such a case, in the method of the comparative example, in the normal state, the left side of the expression (2) is 200 mV, which is a value larger than the determination threshold value of 150 mV. Therefore, in the method of the comparative example, it is erroneously determined that the detection line Ln is in the abnormal state, even if the detection line Ln is in the normal state. On the other hand, in the method of the present embodiment, the left side of the expression (3) is 200 mV, which is a value smaller than the determination threshold value of 300 mV, in the normal state. Therefore, in the method of the present embodiment, no erroneous determination occurs in such a case.

Subsequently, as shown in FIG. 16, it is considered a case where common-mode noise is superimposed on the detection values V2a and V2b of the battery cell Cb2 and the detection values V3a and V3b of the battery cell Cb3. Also in this case, the magnitude of noise is assumed to be 100 mV. In such a case, in the method of the comparative example, the left side of the expression (2) is 200 mV, which is a value larger than the determination threshold value of 150 mV, in the normal state. Therefore, in the method of the comparative example, an erroneous determination occurs even in such a case. On the other hand, in the method of the present embodiment, the left side of the expression (3) is 0 V, which is a value smaller than the determination threshold value of 300 mV, in the normal state. Therefore, in the method of the present embodiment, erroneous determination does not occur even in such a case.

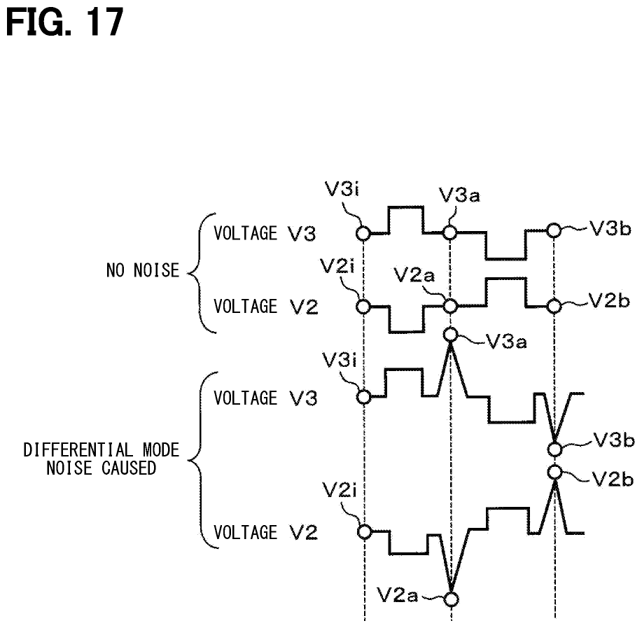

As shown in FIG. 17, in a case where differential-mode noise is superimposed on the detection values V2a and V2b of the battery cell Cb2 and the detection values V3a and V3b of the battery cell Cb3, an erroneous determination may occur in any of the method of the comparative example and the method of the present embodiment. However, in general, noise that affects the voltage detection value of the battery cell is caused by current input and output to and from the battery cell, so common-mode noise is rather assumed. Therefore, according to the present embodiment, it is possible to attain the effect of improving the resistance to noise, particularly the noise resistance to common-mode noise which is considered to affect the voltage detection value of the battery cell.

### Fourth Embodiment

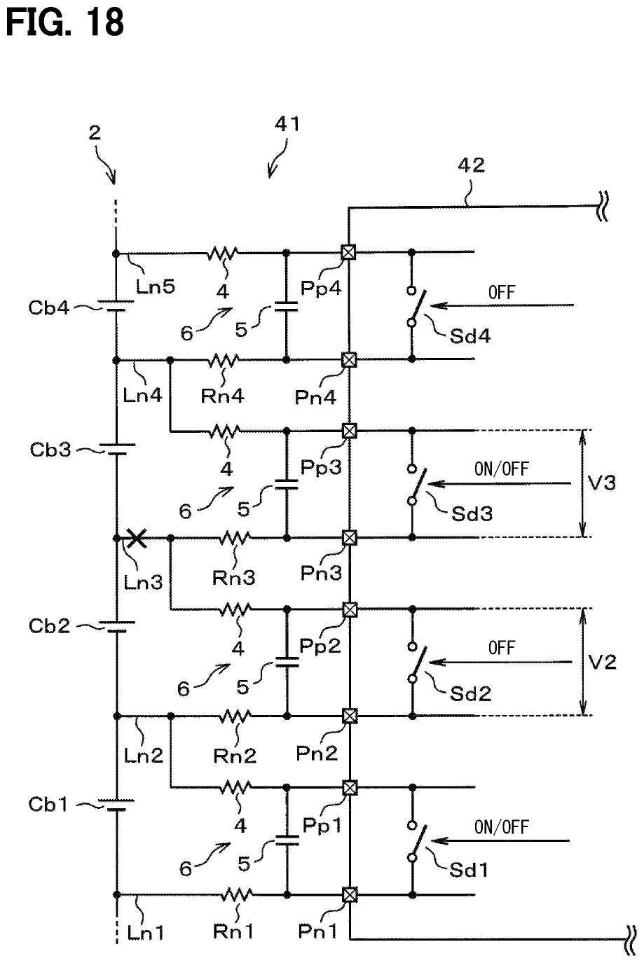

Hereinafter, a fourth embodiment will be described with reference to FIGS. 18 to 20.

As shown in FIG. 18, a battery monitoring device 41 of the fourth embodiment has a filter, between the detection line and the voltage detection circuit, which is modified from the filter of the battery monitoring device 1 of the first embodiment. With such a modification of the filter, respective configurations connecting to the filter are also modified.

A battery monitoring IC 42 of the battery monitoring device 41 has a connection terminal Pp corresponding to the high potential side terminal of each battery cell Cb and a connection terminal Pn corresponding to the low potential side terminal of each battery cell Cb. Each connection terminal Pp is connected to the high potential side terminal of the battery cell Cb via the resistance element 4 of the filter 6 and the detection line Ln. Each connection terminal Pn is connected to the low potential side terminal of the battery cell Cb via the discharge resistance element Rn and the detection line Ln.

In this case, the series circuit of the resistance element 4 and the capacitor 5 constituting the filter 6 is connected between the high potential side terminal of the battery cell Cb and the connection terminal Pn. The output terminal of the filter 6, which is a common connection point between the resistance element 4 and the capacitor 5, is connected to the connection terminal Pp. The short-circuit switch Sd is connected between the connection terminal Pp and the connection terminal Pn inside the battery monitoring IC 42.

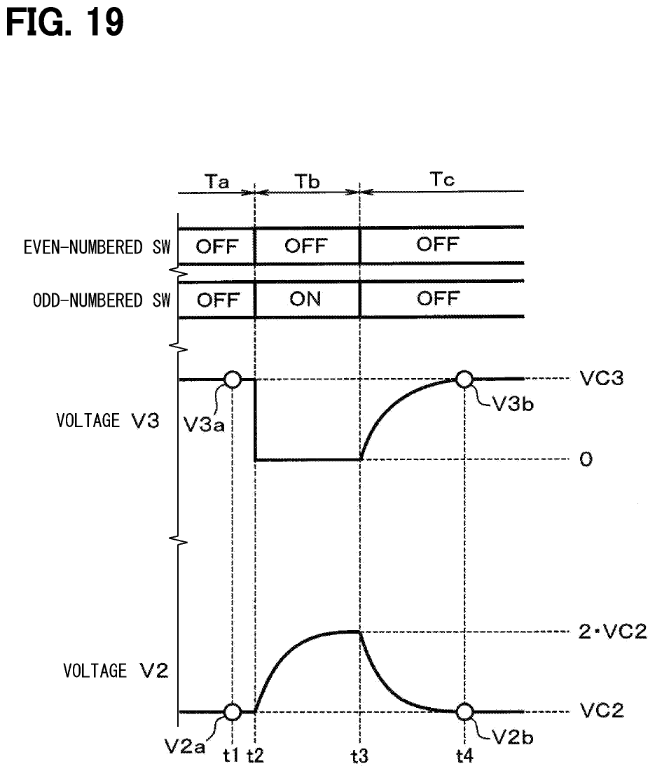

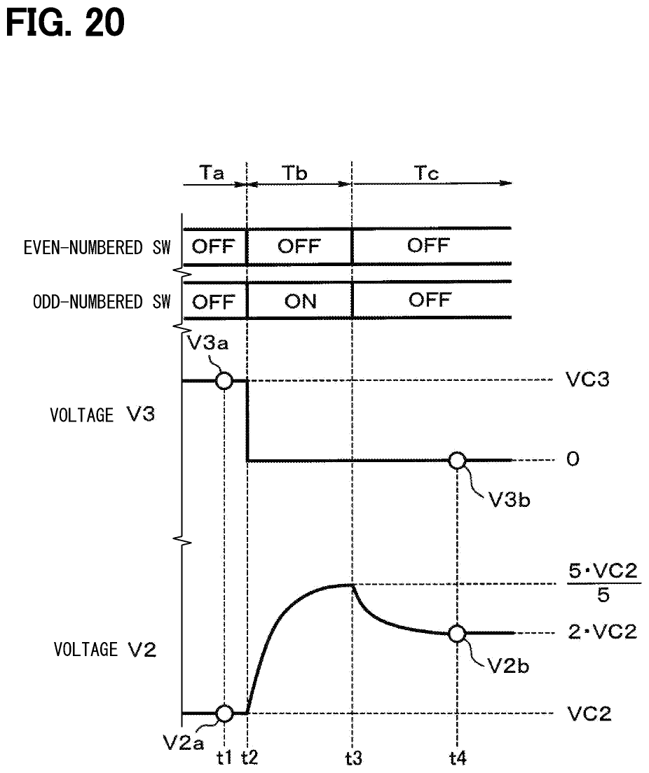

Although not shown, the battery monitoring IC 42 includes a control circuit 8 that executes an abnormality determination process similar to that of the first embodiment. That is, as shown in FIG. 18, in the abnormality determination process, the control circuit 8 controls the short-circuit switch Sd corresponding to the even-numbered cell group to be off, and also controls the short-circuit switch Sd corresponding to the odd-numbered cell group to be turned on and off. As shown in FIGS. 19 and 20, the control circuit 8 detects the voltages of the battery cells Cb2 and Cb3 at an arbitrary time point t1 in the period Ta before the on and off control of the odd-numbered switch and detects the voltages of the battery cells Cb2 and Cb3 at an arbitrary time point t4 in the period Tc after the on and off control of the odd-numbered switch. The control circuit 8 determines the abnormality of the detection line Ln based on the four detected voltage values. Also in this case, the abnormality determination formula shown in the expression (1) is used.

### [1] Operation Related to Abnormality Determination Process in Normal State

As shown in FIG. 19, in a normal state in which the detection line Ln3 is not disconnected, the voltage V3 between the connection terminal Pp3 and the connection terminal Pn3 in the period Ta, that is, the detection value of the voltage of the battery cell Cb3 is the voltage VC3 (for example, 3V), which corresponds to the voltage of the battery cell Cb3. For this reason, the voltage V3a, which is the detection value of the voltage of the battery cell Cb3 at the time point t1, is the voltage VC3. Further, in the normal state, the voltage V2 between the connection terminal Pp2 and the connection terminal Pn2 in the period Ta, that is, the detection value of the voltage of the battery cell Cb2 is the voltage VC2 (for example, 3V) corresponding to the voltage of the battery cell Cb2. Therefore, the voltage V2a, which is the detection value of the voltage of the battery cell Cb2 at the time point t1, is the voltage VC2.

In the normal state, when the odd-numbered switch is turned on at the time point t2, the connection terminal Pp3 and the connection terminal Pn3 are short-circuited, so that the voltage V3 in the normal period Tb is 0 V. In this case, when the odd-numbered switch is turned off at the time point t3, since the capacitor 5 of the filter 6 is charged by the battery cell Cb3, the voltage V3 changes toward the voltage VC3. The slope of the change in the voltage V3 at this time is determined by the time constant of the filter 6, and is a relatively gentle slope.

Thereafter, in the period Tc in the normal state, the voltage V3 reaches the voltage VC3 when the charging of the capacitor 5 of the filter 6 is completed. In the present embodiment, it is assumed that the time point t4 is set at a time point when or after the voltage V3 reaches the voltage VC3 in consideration of the charging time for the capacitor 5. Therefore, the voltage V3b, which is the detection value of the voltage of the battery cell Cb3 at the time point t4, becomes the voltage VC3.

In the normal state, when the odd-numbered switch is turned on at the time point t2, the connection terminal Pp1 and the connection terminal Pn1 are short-circuited. Here, assuming that the voltage of the battery cell Cb1 and the voltage of the battery cell Cb2 are the same voltage value, the voltage V2 in the period Tb in the normal state changes from the voltage VC2 toward the voltage 2·VC2, which is twice the voltage VC2. In this case, when the odd-numbered switch is turned off at the time point t3, the capacitor 5 of the filter 6 is discharged, so the voltage V2 changes toward the voltage VC2.

The slope of the change in the voltage V2 at this time is determined by the time constant of the filter 6, and thus is a relatively gentle slope. Thereafter, in the period Tc in the normal state, the voltage V2 reaches the voltage VC2 when the discharge of the capacitor 5 of the filter 6 is completed. In the present embodiment, the time point t4 is set at a time point when or after the voltage V2 reaches the voltage VC2 in consideration of the discharge time with respect to the capacitor 5. Therefore, the voltage V2b, which is the detection value of the voltage of the battery cell Cb2 at the time point t4, is the voltage VC2.

As described above, in the normal state, the voltage V3a, which is the detection value of the voltage of the battery cell Cb3 at the time point t1, and the voltage V3b which is the detection value of the voltage of the battery cell Cb3 at the time point t4, are both voltage VC3 (for example, 3V). Further, in the normal state, the voltage V2a, which is the detection value of the voltage of the battery cell Cb2 at the time point t1, and the voltage V2b, which is the detection value of the voltage of the battery cell Cb2 at the time point t4, are both voltage VC2 (for example, 3V). Therefore, when each of these detection values is substituted into the above expression (1), the left side of the above expression (1) becomes 0, and the above expression (1) does not hold. Therefore, in the normal state, as a result of the abnormality determination process, the result that the detection line Ln3 is normal is obtained.

### [2] Operation Related to Abnormality Determination Process in Abnormal State

As shown in FIG. 20, in an abnormal state in which the detection line Ln3 is disconnected, the voltage V3 in the period Ta is the voltage VC3 (for example, 3V), similarly to the that in the period Ta in the normal state. Therefore, the voltage V3a, which is the detection value of the voltage of the battery cell Cb3 at the time point t1, is the voltage VC3. Further, in the abnormal state, the voltage V2 in the period Ta is the voltage VC2 (for example, 3V), similarly to the voltage in the period Ta in the normal state. Therefore, the voltage V2a, which is the detection value of the voltage of the battery cell Cb2 at the time point t1, is the voltage VC2.

The voltage V3 in the period Tb in the abnormal state is 0 V, similarly to the voltage in the period Tb in the normal state, since the odd-numbered switch is turned on at the time point t2. In this case, however, even if the odd-numbered switch is turned off at the time point t3, since the detection line Ln3 is disconnected, the capacitor 5 of the filter 6 is not charged by the battery cell Cb3, and the voltage V3 is maintained at 0 V. Therefore, the voltage V3b, which is the detection value of the voltage of the battery cell Cb3 at the time point t4 of the subsequent period Tc, is 0V.

The voltage V2 in the period Tb in the abnormal state rises from the voltage VC2, in the similar manner to that in the period Tb in the normal state, since the odd-numbered switch is turned on at the time point t2. In this case, however, since the detection line Ln3 is disconnected, the voltage V2 changes from the voltage VC2 of the battery cell Cb2 toward the voltage 5·VC2/2, which is 2.5 times the voltage VC2. In this case, when the odd-numbered switch is turned off at the time point t3, the capacitor 5 of the filter 6 is discharged, so the voltage V2 drops.

In this case, however, since the detection line Ln3 is disconnected, the voltage V2 changes toward the voltage 2·VC2 which is twice the voltage VC2. Thereafter, the voltage V2 reaches the voltage 2·VC2 in the period Tc in the abnormal state, when the discharge of the capacitor 5 of the filter 6 is completed.

In the present embodiment, the time point t4 is set at a time point when or after the voltage V2 reaches the voltage 2·VC2 in consideration of the discharge time with respect to the capacitor 5. Therefore, the voltage V2b, which is the detection value of the voltage of the battery cell Cb2 at the time point t4, is the voltage 2·VC2.

As described above, in the abnormal state, the voltage V3a, which is the detection value of the voltage of the battery cell Cb3 at the time point t1, and the voltage V3b, which is the detection value of the voltage of the battery cell Cb3 at the time point t4, are significantly different values. There is a difference of only the voltage VC3 of the battery cell Cb3 between the detection values. Further, in the abnormal state, the voltage V2a, which is the detection value of the voltage of the battery cell Cb2 at the time point t1, and the voltage V2b, which is the detection value of the voltage of the battery cell Cb2 at the time point t4, are significantly different values. There is a difference of only the voltage VC2 of the battery cell Cb2 between the detection values. Therefore, when each of these detection values is substituted into the above expression (1), the left side of the above expression (1) becomes a value of about twice the cell voltage, and the above expression (1) is satisfied. Therefore, in the abnormal state, as a result of the abnormality determination process, the result that the detection line Ln3 is abnormal is obtained.

As described above, in the present embodiment in which the configuration of the filter connected between the detection line and the voltage detection circuit is modified from the configuration of the first embodiment, the similar effects to those of the first embodiment can be achieved. In the configuration of the present embodiment, a standby time due to charging and discharging of the capacitor 5 of the filter 6 occurs even in the normal state. According to the present embodiment, therefore, although the diagnosis time is slightly longer than that of the first embodiment, the diagnosis time can be shortened as compared with the comparative example.

### Other Embodiments

The present disclosure is not limited to the embodiments that have been described above and illustrated in the drawings, but can arbitrarily be modified, combined, or expanded without departing from the gist of the present disclosure.

The numerical values and the like shown in each of the above embodiments are merely examples, and the present disclosure is not limited thereto.

The short-circuit switch Sd is not limited to the N-channel MOSFET, and various semiconductor switching elements such as a P-channel MOSFET and a bipolar transistor, an analog switch, and the like can be adopted.

The filter 6 may have a configuration that is connected between the detection line Ln and the voltage detection circuit 7, and the specific configuration thereof can be appropriately changed.

The determination threshold Th is not limited to 0, and may be set to a value capable of determining an abnormality in the detection line Ln in consideration of various errors in the applied circuit. Further, the determination threshold value Th may be set to a value having a predetermined range. Further, the abnormality determination formula is not limited to the one shown in each of the above embodiments, and can be appropriately changed.

The present disclosure is not limited to the battery monitoring devices 1 and 41 that monitor the assembled battery 2 mounted on the vehicle, but may be applied to all the battery monitoring devices that monitor the assembled battery having a configuration in which a plurality of battery cells are connected in series.

The present disclosure has been described based on the embodiments, but it is understood that the present disclosure is not limited to the embodiments or configurations thereof. The present disclosure encompasses various modifications and variations within the scope of equivalents. In addition, various combinations and configurations, as well as other combinations and configurations that include only one element, more, or less, fall within the scope and spirit of the present disclosure.

What is claimed is:

1. A battery monitoring device for monitoring an assembled battery having a plurality of battery cells connected in series, the battery monitoring device comprising:
a plurality of detection lines connected to both terminals of the plurality of battery cells;
a voltage detection circuit configured to detect voltages of the plurality of battery cells through the detection lines;
a plurality of filters correspondingly provided for the plurality of battery cells, and connected between the detection lines and the voltage detection circuit;
a plurality of short-circuit switches correspondingly provided for the plurality of battery cells and each configured to short-circuit between a pair of detection lines connected to the both terminals of a corresponding battery cell; and
an abnormality determination circuit configured to control the plurality of short-circuit switches and determine whether or not an abnormality has occurred in the plurality of detection lines, wherein
the plurality of battery cells includes a first battery cell and a second battery cell adjacent to the first battery cell,
the plurality of short-circuit switches includes a first switch corresponding to the first battery cell and a second switch corresponding to the second battery cell,
the abnormality determination circuit executes an on and off control to turn the second switch from an off state to an on state, and then to the off state again while keeping the first switch in an off state,
the abnormality determination circuit detects voltages of the first battery cell and voltages of the second battery cell before and after execution of the on and off control, and
the abnormality determination circuit determines an abnormality of a corresponding detection line based on values of four voltages detected.

2. The battery monitoring device according to claim 1, wherein
the on and off control is a first on and off control,
the abnormality determination circuit executes a second on and off control to turn the first switch from the off state to an on state and then to the off state again while keeping the second switch in the off state, and
the abnormality determination circuit executes the second on and off control prior to the execution of the first on and off control.

3. The battery monitoring device according to claim 1, wherein
the abnormality determination circuit determines the abnormality of the corresponding detection line based on a difference between the voltages of the first battery cell before and after the execution of the on and off control, and a difference between the voltages of the second battery cell before and after the execution of the on and off control.

4. The battery monitoring device according to claim 3, wherein
the abnormality determination circuit determines that the abnormality has occurred in the corresponding detection line on condition that a sum of the difference between the voltages of the first battery cell before and after the execution of the on and off control and the difference between the voltages of the second battery cell before and after the execution of the on and off control is larger than a predetermined determination threshold value.

5. The battery monitoring device according to claim 1, wherein
the abnormality determination circuit determines the abnormality of the corresponding detection line based on a difference between the voltage of the first battery cell and the voltage of the second battery cell before the execution of the on and off control, and a difference between the voltage of the first battery cell and the voltage of the second battery cell after the execution of the on and off control.

6. The battery monitoring device according to claim 5, wherein
the abnormality determination circuit determines that the abnormality has occurred in the corresponding detection line on condition that a sum of the difference between the voltage of the first battery cell and the voltage of the second battery cell before the execution of the on and off control, and the difference between the voltage of the first battery cell and the voltage of the second battery cell after the execution of the on and off control is larger than a predetermined determination threshold value.
